(19) United States
(12) Patent Application Publication
(10) Pub. No.: US 2008/0047826 A1
(43) Pub. Date: Feb. 28, 2008

(54) Protective coating method of pervoskite structure for SOFC interconnection

(75) Inventors: Chi-Ting Lin, Taoyuan (TW); Der-Jun Jan, Longtan Township (TW); Chi-Fong Ai, Taoyuan (TW)

Correspondence Address: TROXELL LAW OFFICE PLLC, SUITE 1404, 5205 LEESBURG PIKE, FALLS CHURCH, VA, 22041, US

(73) Assignee: ATOMIC ENERGY COUNCIL-INSTITUTE OF NUCLEAR ENERGY RESEARCH, TAOYUAN (TW)

(21) Appl. No.: 11/508,236

(22) Filed: Aug. 23, 2006

(51) Int. Cl. C23C 14/00

(52) U.S. Cl. 204/192.12

(57) ABSTRACT

A protective coating is formed on a stainless interconnecting plate used in solid oxide fuel cell (SOFC). With the protective coating, a contact resistance of the plate is effectively lowered. Anode and cathode of SOFC are also prevented from being poisoned by chromium diffusion from the plate. Therefore, after a long time of use under a high temperature, a degradation rate for power generating of SOFC is reduced; and, thus, a working hour is prolonged. Hence, the SOFC can be mass-produced and large-scaled.

### FIELD OF THE INVENTION

The present invention relates to a method for protective coating; more particularly, relates to forming a protective coating of a pervoskite structure on a stainless interconnecting plate used in solid oxide fuel cell (SOFC).

### DESCRIPTION OF THE RELATED ARTS

A few methods for a protective coating of a pervoskite structure on a stainless interconnecting plate include a radio frequency (RF) plasma magnetron sputtering, a plasma spray and sol-gel, and an ion beam sputtering to paste a protective coating of La_{0.67}Sr_{0.33}MnO₃ (LSM) to obtain the pervoskite structure through annealing.

But these methods have some disadvantages. Concerning the RF plasma magnetron sputtering, the RF power supply used is expansive and its deposition rate is slower than that of a pulsed DC power supply. Concerning the sol-gel, it is hard to control its crystallization and its adhesion of coating film is not good; in addition, its structure is not close-grain ed, thus it is not a good protective coating under a high temperature. Concerning the plasma spray, the plasma spray particles are bigand so the thin film obtained has a porous structure, which does not suit to be a protective coating.

A prior art of U.S. Pat. No. 5,426,003, “Method of forming a plasma sprayed interconnection layer on an electrode of an electrochemical cell”, fabricates an interconnecting layer through a plasma spray. But the thin film obtained is not close-grained, the post-processing is not easy and the cost is high too. Another prior art of U.S. Pat. No. 5,609,921, “Suspension plasma spray”. A protective coating is deposited through a plasma spray. Because the thin film obtained through the plasma spray is rapidly cooled down, some defects may happen to the thin film and thus the protective coating may fail under a high temperature.

A ceramic interconnection can be obtained using the above prior arts, but it is expansive. On the contrary, a stainless substrate is cheap and is easily processed. But an interface resistance between an anode and a cathode increases after a long time of operation under a high temperature; and its anode and cathode may be poisoned by chromium. Therefore a protective coating is required to block the chromium from diffusing to the anode and the cathode. Yet the above prior art is not either close-grained or tightly adhered. Hence, the prior arts do not fulfill users' requests on actual use.

### SUMMARY OF THE INVENTION

The main purpose of the present invention is to preparing a stainless interconnecting plate having a protective coating of pervoskite structure to be used in SOFC to effectively reduce a contact resistance of the stainless interconnecting plate and to prevent anode and cathode of SOFC from being poisoned by the diffusion of chromium from the stainless interconnecting plate.

To achieve the above purpose, the present invention is a protective coating method of a pervoskite structure for SOFC interconnection, comprising steps of: (a) deposing a stainless interconnecting plate on a holder substrate in a vacuum chamber and pumping the vacuum chamber to a vacuity through a pumping device; (b) accessing a gas into the vacuum chamber to maintain a gas pressure and processing a DC discharge with a pulsed DC power supply to obtain a plasma; and (c) bombarding a pervoskite structure target on a surface of the target by reactive ions in the plasma through a field control to sputter the pervoskite structure on the stainless interconnecting plate to obtain a protective coating and processing the stainless interconnecting plate through annealing to obtain the stainless interconnecting plate having the protective coating of the pervoskite structure. Accordingly, a novel protective coating method of a pervoskite structure for SOFC interconnection is obtained.

### BRIEF DESCRIPTION OF THE DRAWINGS

The present invention will be better understood from the following detaiIed description of the preferred embodiment according to the present invention, taken inconjunction with the accompanying drawings, in which

FIG. 1 is the view showing the device used according to the present invention;

FIG. 2 is the view showing the flow chart of the present invention;

FIG. 3 is the view showing the X-ray powder diffraction analysis;

FIG. 4 is the view showing the protective coating by the electron microscope; and

FIG. 5 is the view showing the ASR.

### DESCRIPTION OF THE PREFERRED EMBODIMENT

The following description of the preferred embodiment is provided to understand the features and the structures of the present invention.

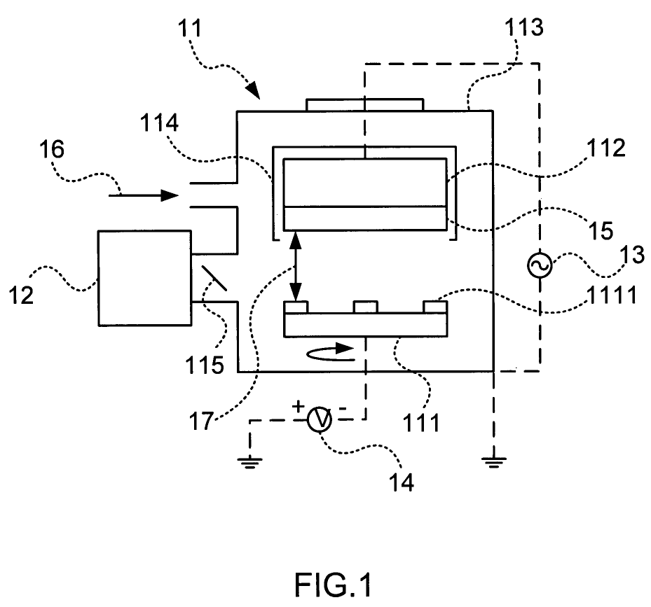

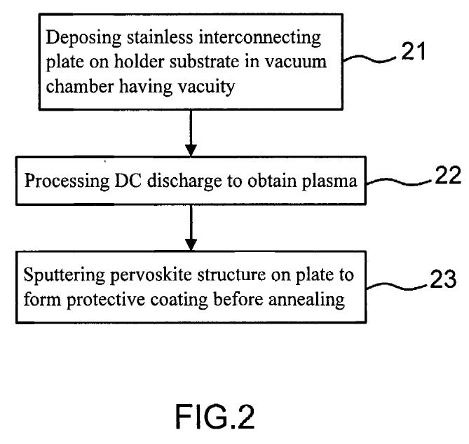

Please refer to FIG. 1 and FIG. 2, which are views showing a device used and a flow chart of the present invention. As shown in the figures, the present invention is a protective coating method of a pervoskite structure for SOFC interconnection. A device used according to the present invention is a vacuum chamber 11, comprising a holder substrate 111, a cathode 112, at least one anode 113, a shielding shell 114 and a valve 115. The vacuum chamber 11 connects to a pumping device 12, a pulsed DC power supply 13 and a bias 14, where the pulsed DC power supply 13 is connected with the cathode 112 and the anode 113 is the shell of the vacuum chamber 11.

The present invention prepares a protective coating of a pervoskite structure on a stainless inter-connecting plate through the following steps:

(a) Deposing a stainless inter-connecting plate on a holder substrate in a vacuum chamber having a vacuity 21: A stainless interconnecting plate 1111 is deposed on a holder substrate 111 in a vacuum chamber 11 and the vacuum chamber 11 obtains a vacuity by exhausting air through a pumping device. Therein, the stainless inter-connecting plate 1111 is made of a Fe(iron)-base alloy, a Cr(chromium)-base alloy, a Ni(nickel)-base alloy or an alloy made of any combination of the above alloys. The vacuity is below 10⁻⁴ torr. The holder substrate 111 is further equipped with a heating rotator to heat and rotate the holder substrate 111. The cathode 112 is cooled down with a cooling water to absorb heat from the pervoskite structure target 15 on plasma discharging. The shielding shell 114 preserves plasma on a surface of the pervoskite structure target 15 to keep from wasting. The holder substrate 111 has a potential further added by a bias 14. The bias 14 has a voltage located between −150 volts (V) and 0V to enhance the speed and efficiency of the sputtering and forming of the protective coating. The potential of the holder substrate 111 and that of the anode 113 are ground potentials. And the molecular formula of the pervoskite structure target 15 is ABO₃, where the ‘A’ is LnₓE₁₋ₓ; the Ln is a rare earth element; the E is an alkaline—earth metal; the x is a value greater than 0.1 and smaller than 0.9; and the B is a transition metal.

(b) Processing a DC discharge to obtain a plasma 22: After the vacuum chamber 11 obtains the default vacuity, a gas is accessed, which is argon (Ar), krypton (Kr), oxygen (O₂) or a gas mixed of any combination of the above gases. A valve 115 is used to remain the vacuum chamber 11 in a pressure between 0.001 torr and 0.1 torr. The pulsed DC power supply 13 is processed with a DC discharge to obtain a plasma from the gas, where the DC discharge has a volt lower than 1000V; and the pulsed DC power supply 13 has a frequency between 0 and 350 kilo hertz (KHz). The power and time used is decided according to the state on fabricating the protective coating of a pervoskite structure.

(c) Sputtering a pervoskite structure on the stainless inter-connecting plate to form a protective coating before annealing 23: Reactive ions obtained from the plasma and the gas bombard the pervoskite structure target 15 with a field control to sputter the pervoskite structure on the stainless interconnecting plate 1111 for forming a protective coating. Then the stainless interconnecting plate 1111 having the protective coating is put in a furnace for processing an annealing to further obtain a stainless interconnecting plate 1111 having the protective coating of the pervoskite structure, where the temperature for the annealing is higher than 600 Celsius degrees (° C.).

Thus, a novel protective coating method of a pervoskite structure for SOFC interconnection is obtained.

Take fabricating a protective coating of a pervoskite structure for a stainless interconnecting plate of Crofer22, for example. The fabricating method comprises the following steps:

(a) A stainless interconnecting plate of Crofer22 having an area of 10×10 mm (millimeter) and a thickness of 5 mm is put on a holder substrate 111 in the vacuum chamber 11. Then the valve 115 is opened to exhaust gas by the pumping device to obtain a vacuity of 5×10⁻⁵ torr.

(b) A gas is accessed, which is Ar with a flow rate of 60 standard cubic centimeters per minute (sccm). The pressure in the vacuum chamber 11 is kept at 0.02 torr by using the valve 115 The cathode 112 is cooled down with a cooling water. The potentials of the holder substrate 111 is a ground potential. The distance 17 between the holder substrate 111 and the pervoskite structure target 15 is about 5 centimeters (cm). The shell of the vacuum chamber 11 is the anode 113 with a ground potential. Then the pulsed DC power supply 13 is turned on for a DC discharge between two electrodes to produce a plasma through reacting with the gas. There in, the DC discharge has a voltage of 200V; and the pulsed DC power supply has a frequency of 350KHz together with a power of 100 walts run for 2 hours.

(c) Reactive gas ions in the plasma bombard a pervoskite structure target 15 under a field control to sputter a pervoskite structure (La_{0.67}Sr_{0.33}MnO₃, LSM) on the stainless interconnecting plate to form a protective coating. Then the stainless interconnecting plate 1111 having the protective coating is processed with four periods of one hour of annealing at 600° C., 700° C., 800° C. and 900° C. separately.

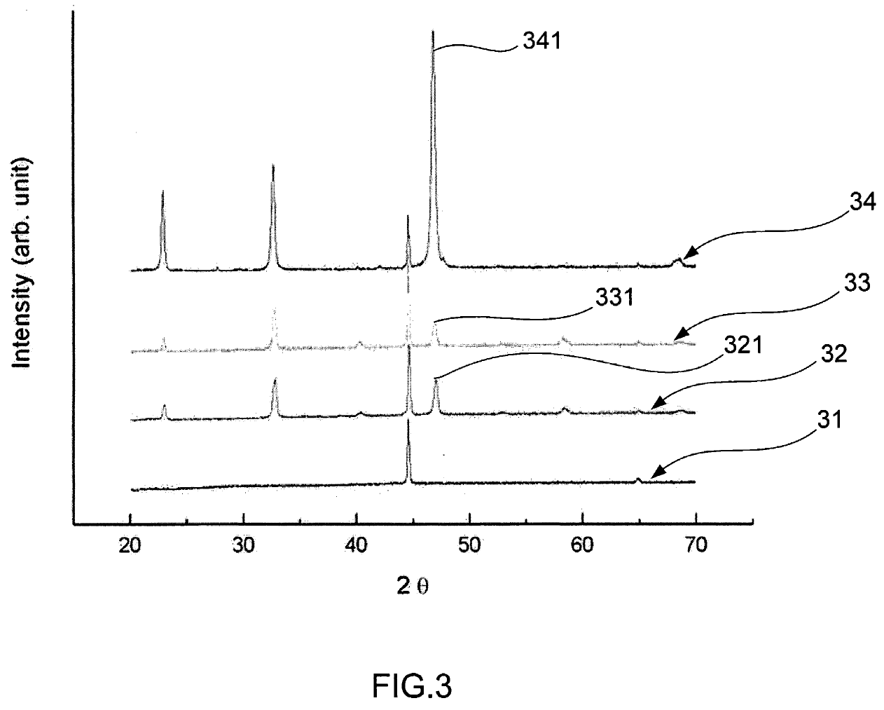

Please refer to FIG. 3 to FIG. 5, which are views showing an X-ray powder diffraction analysis, a protective coating by the electron microscope and an area specific resistance (ASR). As shown in FIG. 3, there are a first diffraction curve 31, a second diffraction curve 32, a third diffraction curve 33 and a fourth diffraction curve 34, where the first diffraction curve 31 is the diffraction curve obtained from the annealing at 600° C.; the se con d diffraction curve 32, at 700° C.; the third diffraction curve 33, at 800° C.; and the fourth diffraction curve 34, at 900° C. From the first diffraction curve 31, the second diffraction curve 32, the third diffraction curve 33 and the fourth diffraction curve 32, it is known that, when the annealing temperature is higher than 700° C., a peak 321, 331, 341 is obtained for the protective coating of the pervoskite structure on processing one hour of an annealing.

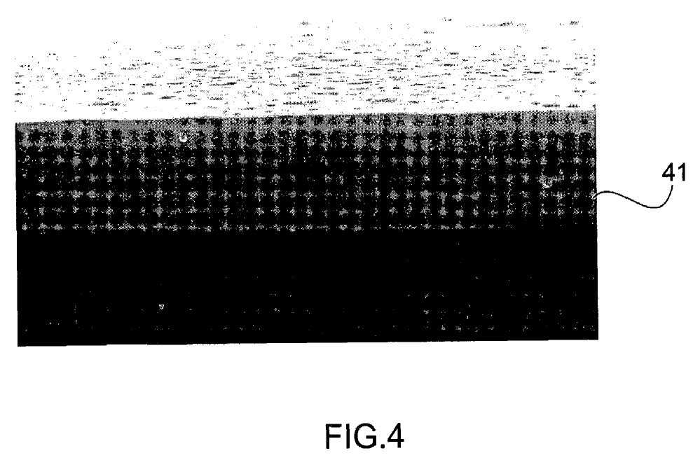

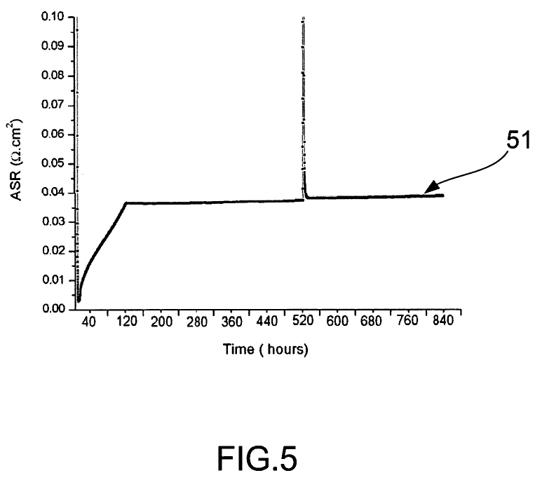

As a result, a protective coating of the pervoskite structure processed with one hour of annealing at 700° C. is obtained; and, as shown in FIG. 4, its cross-section 41 is close-grained. Then the protective coating of the pervoskite structure is measured with its are a specific resistance (ASR). As shown in FIG. 5, by measuring at 750° C. for hundreds of hours, a diffraction curve 51 is obtained, whose resistance is about 0.0395 Ωcm², smaller than the least requirement of 1 Ωcm² for a solid oxide fuel cell (SOFC).

To sum up, the present invention is a protective coating method of a pervoskite structure for SOFC interconnection, where a close-grained protective coating of a pervoskite structure is formed after an annealing to a stainless interconnecting plate sputtered with a protective coating; and, by doing so, easy-fabricated and cheap stainless steel can be used as an interconnecting plate for SOFC used in a high temperature.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A protective coating method of a pervoskite structure for SOFC interconnection, comprising:
(a) deposing a stainless inter-connecting plate on a holder substrate in a vacuum chamber and pumping said vacuum chamber through a pumping device to obtain a vacuity;
(b) accessing a gas into said vacuum chamber to maintain a gas pressure and processing a DC discharge with a pulsed DC power supply to obtain a plasma; and
(c) bombarding a pervoskite structure target on a surface of said target by reactive ions in said plasma with a field control to sputter said pervoskite structure on said stainless interconnecting plate to obtain a protective coating and processing annealing to said stainless interconnecting plate to obtain said stainless inter-connecting plate having said protective coating of said pervoskite structure.

2. The method according to claim 1. wherein said stainless inter-connecting plate is made of a material selected from a group consisting of a Fe (iron)-base alloy, a Cr(chromium)-base alloy and a Ni(nickel)-base alloy.

3. The method according to claim 1.
wherein said pervoskite structure has a molecular formula of ABO₃;
wherein said A is LnₓE₁₋ₓ, said Ln is a rare earth element, said E is an alkaline—earth metal, and said X is greater than 0.1 and is smaller than 0.9; and
wherein said B is a transition metal.

4. The method according to claim 1
wherein said gas is selected from a group consisting of argon (Ar), krypton (Kr) and oxygen (O₂).

5. The method according to claim 1.
wherein said DC discharge has a voltage smaller than 1000 volts (V).

6. The method according to claim 1.
wherein said gas pressure is located between 0.01 torr and 0.1 torr.

7. The method according to claim 1
wherein said pulsed DC power supply has a frequency between 0 hertz (Hz) and 1 mega Hz (MHz).

8. The method according to claim 1
wherein said pulsed DC power supply is connected with a cathode.

9. The method according to claim 1
wherein said holder substrate has a potential further added by a bias; and
wherein said bias has a voltage located between −150V and 0V.

10. The method according to claim 1
wherein said holder substrate has a ground potential.

11. The method according to claim 1
wherein said annealing has a temperature higher than 600 Celsius degrees (° C.).
